(19) United States
(12) Patent Application Publication
(10) Pub. No.: US 2015/0004769 A1
(43) Pub. Date: Jan. 1, 2015

(54) Method of Semiconductor Integrated Circuit Fabrication

(71) Applicant: Taiwan Semiconductor Manufacturing Company, Ltd., Hsin-Chu (TW)

(72) Inventors: Yi-Wei Chiu, Kaohsiung (TW); Tzu Chan Weng, Kaohsiung City (TW); Li Te Hsu, Shanhua Township (TW); Hsu-Yu Huang, Tainan City (TW)

(21) Appl. No.: 13/930,045

(22) Filed: Jun. 28, 2013

(51) Int. Cl. H01L 21/8234

(52) U.S. Cl. CPC H01L 21/823468; H01L 21/823418
USPC 438/303

(57) ABSTRACT

A method of fabricating a semiconductor device is disclosed. A substrate with protrusion structures is provided. A patterned photoresist layer is formed over the substrate, including the protrusion structures. An ion-implantation is applied to the substrate, including to the patterned photoresist layer and an outer portion of the patterned photoresist layer is formed a hardened portion. A two-stage-striping process is performed to remove the patterned photoresist layer. The first stage is performing a low-temperature-dry-etch to substantially remove the hardened portion of the patterned photoresist layer. The second stage is performing a wet etch to remove the remaining patterned photoresist layer.

### BACKGROUND

The semiconductor integrated circuit (IC) industry has experienced rapid growth. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, gate structures including one or more layers, referred to as gate stacks, are often used in transistors. Gate stacks may experience breaking/peeling issues during later processing, such as a post ion-implantation photoresist striping process. Although existing methods of fabricating semiconductor devices have been generally adequate for their intended purposes, they have not been entirely satisfactory in all respects. Improvements in this area are desired.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flowchart of an example method for fabricating a semiconductor device constructed according to various aspects of the present disclosure.

FIG. 2 is a cross-section view of a semiconductor device precursor according to various aspects of the present disclosure.

FIGS. 3 to 6 are cross-sectional views of an example semiconductor device at fabrication stages constructed according to the method of FIG. 1.

### DETAILED DESCRIPTION

It is to be understood that the following disclosure provides many different embodiments, or examples, for implementing different features of the disclosure. Specific examples of components and arrangements are described below to simplify the present disclosure. These are, of course, merely examples and are not intended to be limiting. Moreover, the performance of a first process before a second process in the description that follows may include embodiments in which the second process is performed immediately after the first process, and may also include embodiments in which additional processes may be performed between the first and second processes. Various features may be arbitrarily drawn in different scales for the sake of simplicity and clarity. Furthermore, the formation of a first feature over or on a second feature in the description that follows may include embodiments in which the first and second features are formed in direct contact, and may also include embodiments in which additional features may be formed between the first and second features, such that the first and second features may not be in direct contact.

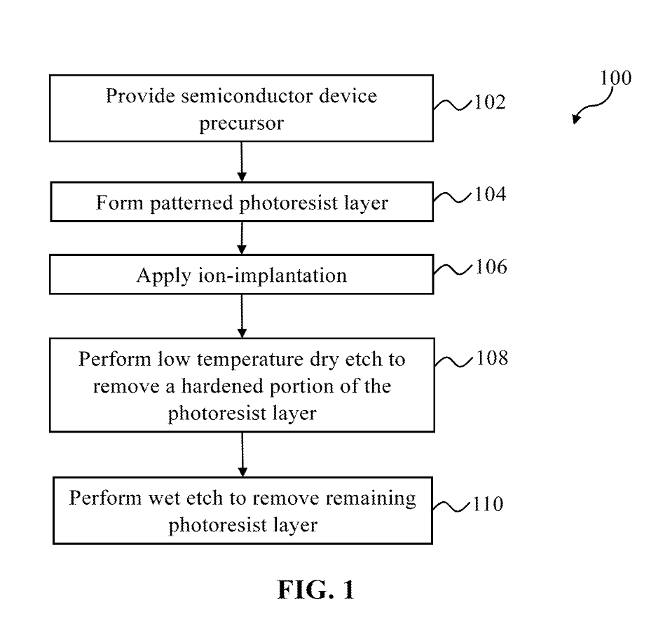

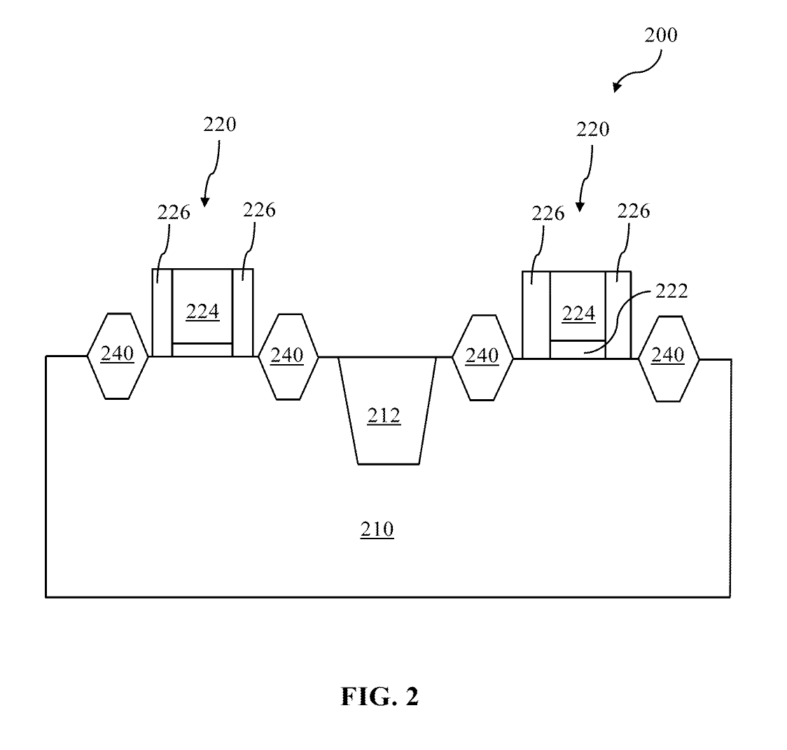

FIG. 1 is a flowchart of one embodiment of a method 100 of fabricating one or more semiconductor devices according to aspects of the present disclosure. The method 100 is discussed in detail below, with reference to an example semiconductor device precursor 200 and an example semiconductor device 300, shown in FIGS. 2 to 8.

Referring to FIGS. 1 and 2, the method 100 begins at step 102 by providing semiconductor device precursor 200 having a substrate 210. The substrate 210 includes silicon. Alternatively or additionally, the substrate 210 may include other elementary semiconductor such as germanium. The substrate 210 may also include a compound semiconductor such as silicon carbide, gallium arsenic, indium arsenide, and indium phosphide. The substrate 210 may include an alloy semiconductor such as silicon germanium, silicon germanium carbide, gallium arsenic phosphide, and gallium indium phosphide. In one embodiment, the substrate 210 includes an epitaxial layer. For example, the substrate 210 may have an epitaxial layer overlying a bulk semiconductor. Furthermore, the substrate 210 may include a semiconductor-on-insulator (SOI) structure. For example, the substrate 210 may include a buried oxide (BOX) layer formed by a process such as separation by implanted oxygen (SIMOX) or other suitable technique, such as wafer bonding and grinding.

The semiconductor device precursor 200 may also include various p-type doped regions and/or n-type doped regions, such as n-well and p-well, implemented by a process such as ion implantation and/or diffusion.

The semiconductor device precursor 200 may also include various isolation features 212. The isolation features 212 separate various device regions in the substrate 210. The isolation features 212 include different structures formed by using different processing technologies. For example, the isolation features 212 may include shallow trench isolation (STI) features. The formation of a STI may include etching a trench in the substrate 210 and filling in the trench with insulator materials such as silicon oxide, silicon nitride, or silicon oxynitride. The filled trench may have a multi-layer structure such as a thermal oxide liner layer with silicon nitride filling the trench. A chemical mechanical polishing (CMP) may be performed to polish back excessive insulator materials and planarize the top surface of the isolation features.

In the present embodiment, the semiconductor device precursor 200 includes a plurality of protrusion structure 220 formed over a surface of the substrate 210. In one embodiment, the protrusion structure 220 is polysilicon gate stack. As an example, the polysilicon gate stack 220 may include a dielectric layer 222 and a polysilicon layer 224. The dielectric layer 222 includes silicon oxide, silicon nitride, or any other suitable materials. The protrusion structure 220 may be formed by a procedure including deposition, photolithography patterning, and etching processes. The deposition processes include chemical vapor deposition (CVD), physical vapor deposition (PVD), atomic layer deposition (ALD), other suitable methods, and/or combinations thereof. The photolithography patterning processes include photoresist coating (e.g., spin-on coating), soft baking, mask aligning, exposure, post-exposure baking, developing the photoresist, rinsing, drying (e.g., hard baking), other suitable processes, and/or combinations thereof. The etching processes include dry etching, wet etching, and/or other etching methods (e.g., reactive ion etching).

The following description will be directed to the polysilicon gate, it being understood that various types of protrusion structures and various processes can benefit from the present invention.

The semiconductor device precursor 200 may also include sidewall spacers 226 formed on the sidewalls of the polysilicon gate 220. The sidewall spacers 226 may include a dielectric material such as silicon oxide. Alternatively, the sidewall spacers 226 may include silicon nitride, silicon carbide, silicon oxynitride, or combinations thereof. The sidewall spacers 226 may be formed by deposition and dry etching processes known in the art.

In one embodiment, the semiconductor device precursor 200 also includes source/drain (S/D) features 240 in the substrate 210, separated by a respective polysilicon gate 220. As an example, the S/D feature 240 is formed by recessing a portion of the substrate 210 to form S/D recessing trenches and epitaxially growing a semiconductor material layer in the S/D recessing trenches. The semiconductor material layer includes element semiconductor material such as germanium (Ge) or silicon (Si); or compound semiconductor materials, such as gallium arsenide (GaAs), aluminum gallium arsenide (AlGaAs); or semiconductor alloy, such as silicon germanium (SiGe), gallium arsenide phosphide (GaAsP). The epitaxial processes include CVD deposition techniques (e.g., vapor-phase epitaxy (VPE) and/or ultra-high vacuum CVD (UHV-CVD)), molecular beam epitaxy, and/or other suitable processes. The S/D features may be formed by one or more epitaxy or epitaxial (epi) processes. The S/D features may be in-situ doped during the epitaxy process.

Source and drain features are often swapped, depending on the transistor's eventual use and electrical configuration. Therefore, the terms “source” and “drain” are deemed to be interchangeable.

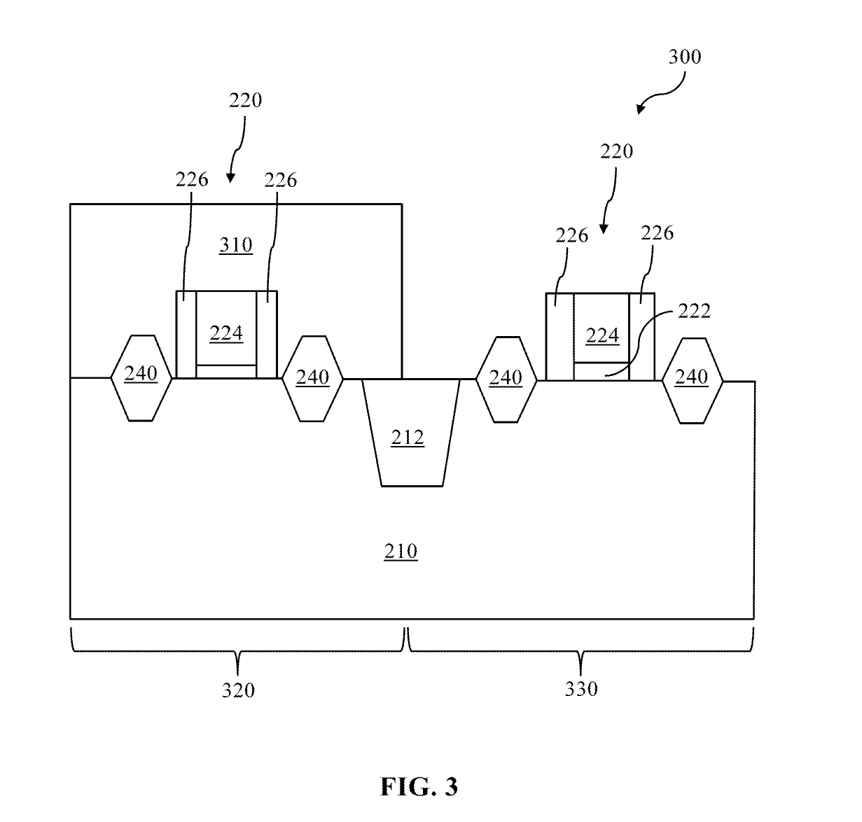

Referring to FIGS. 1 and 3, once the semiconductor device precursor 200 is received, the method 100 proceeds to step 104 by forming a patterned photoresist layer 310 over the substrate 210. The patterned photoresist layer 310 may be formed by photolithography patterning processes including photoresist coating, radiation exposing, developing processes to cover a first region 320 and exposing a second region 330 in the substrate 210. For example, the first region 320 is an NFET region and the second region 330 is a PFET region. In the present embodiment, both first and second region, 320 and 330, have one or more protrusion structures 220, respectively. In another embodiment, the first region 320 has one or more protrusion structure 220, while the second region 330 does not. The photoresist layer 310 is configured such that when it is exposed to light, chemical reactions happen in exposed regions of the photoresist layer 310, which increase or decrease solubility of the exposed regions. If the exposed regions become more soluble, the photoresist layer 310 is referred to as a positive photoresist. If the exposed regions become less soluble, the photoresist layer 310 is referred to as a negative photoresist. After receiving a radiation exposure, a developing solution may be utilized to remove portions of the photoresist layer 310. The developing solution may remove the exposed or unexposed portions depending on the type of photoresist layer 310.

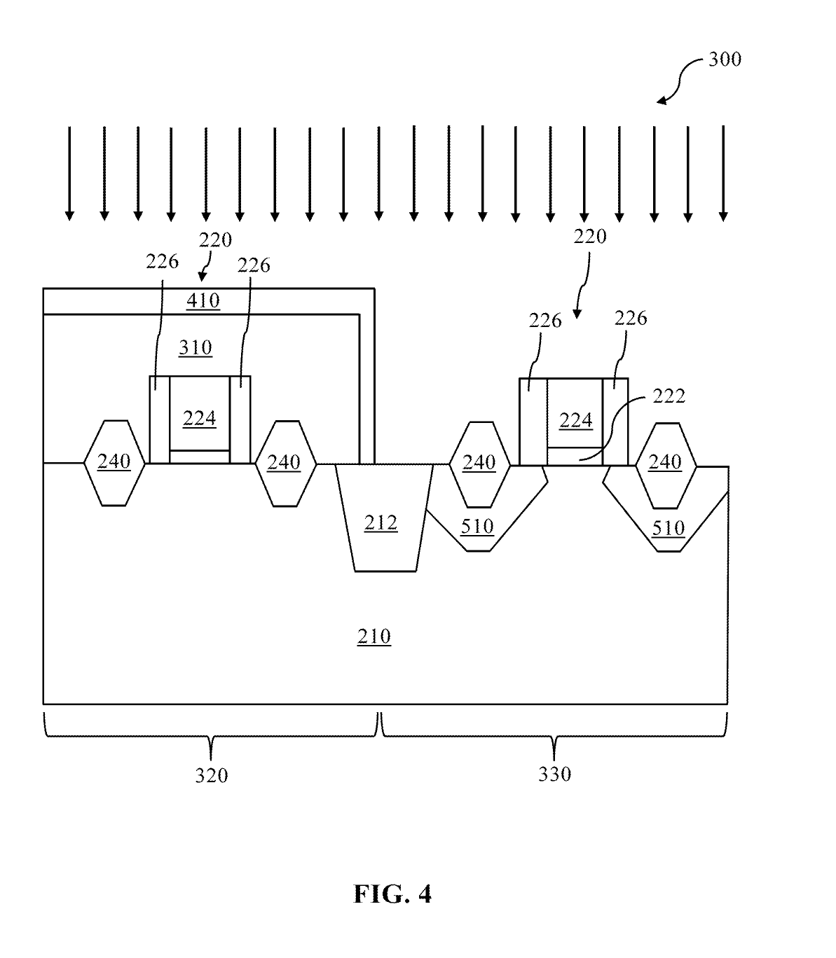

Referring FIGS. 1 and 4, the method 100 proceeds to step 106 by performing one or more ion-implantation (illustrated by arrows in FIG. 4) over the substrate 210 with the patterned photoresist layer 310 to form a doped regions 510 in the second region 330. In one embodiment, the doped regions 510 are formed under the source/drain features 240. For the sake of example, the doped regions 510 include a lightly doped source/drain (LDD) region substantially aligned with the polysilicon gate 220. For the sake of further example, another ion-implantation is performed to form heavily doped source and drain (S/D) regions 510 substantially aligned with associated sidewall spacers 226. The ion implantation process may implant p-type dopants (such as boron or indium), n-type dopants (such as phosphorous or arsenic), or a combination thereof.

The ion implantation process is performed at a suitable energy and dosage to achieve desired characteristics of the integrated circuit device. For example, an ion-implant dosage is about 3×10¹⁰ ions/cm². For another example, ion-implant energy is about 400 keV. The ion-implantation process may cause physical and chemical changes in the patterned photoresist layer 310 and result that a portion of the patterned photoresist layer 310 is hardened (designated as a portion 410 in FIG. 4). The portion 410 is also referred to as a hardened portion or a crust of the patterned photoresist layer 310. Such physical and chemical changes result from various phenomena including dopants embedded in the patterned photoresist layer 310 during the ion implantation process, cross-linking of polymer chains of the patterned photoresist layer 310 during the ion implantation process (caused by the dopants altering polymer properties of the photoresist material, which carbonizes and hardens portions of the patterned photoresist layer 310 exposed to the dopants), dopants sputtering atoms from the substrate 210 to the patterned resist layer 310, other phenomena, or a combination thereof. A thickness of the hardened portion 410 may vary according to types of photoresist material of the patterned photoresist layer 310, parameters of the ion-implant, or a combination thereof. In one embodiment, a thickness of the hardened portion 410 is about 500 nm.

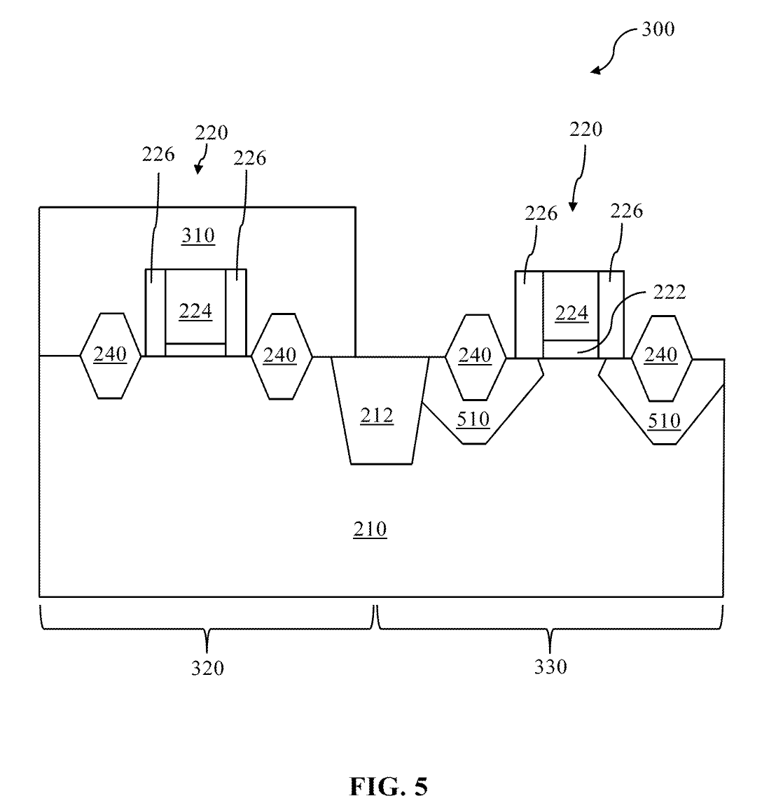

Referring FIGS. 1 and 5, the method 100 proceeds to step 106 by performing a first stage of a two-stage-striping process. In the present embodiment, the first stage includes a low temperature dry etch to remove the hardened portion 410. In one embodiment, the low temperature dry etch is an oxygen-contained plasma etch with temperature less than 400° C. In another embodiment, the low temperature dry etch is an H₂/N₂/H₂N₂/O₂-contained plasma etch with temperature less than 400 ° C. Since different types of photoresist and ion-implantation may result in different thicknesses of the hardened portion 410 and different reactivities to the low temperature dry etch process, a thickness of the hardened portion 410 and an etch rate with respect to the low temperature dry etch may be measured first, for setting etching parameters such as etch time, to completely remove the hardened portion 410.

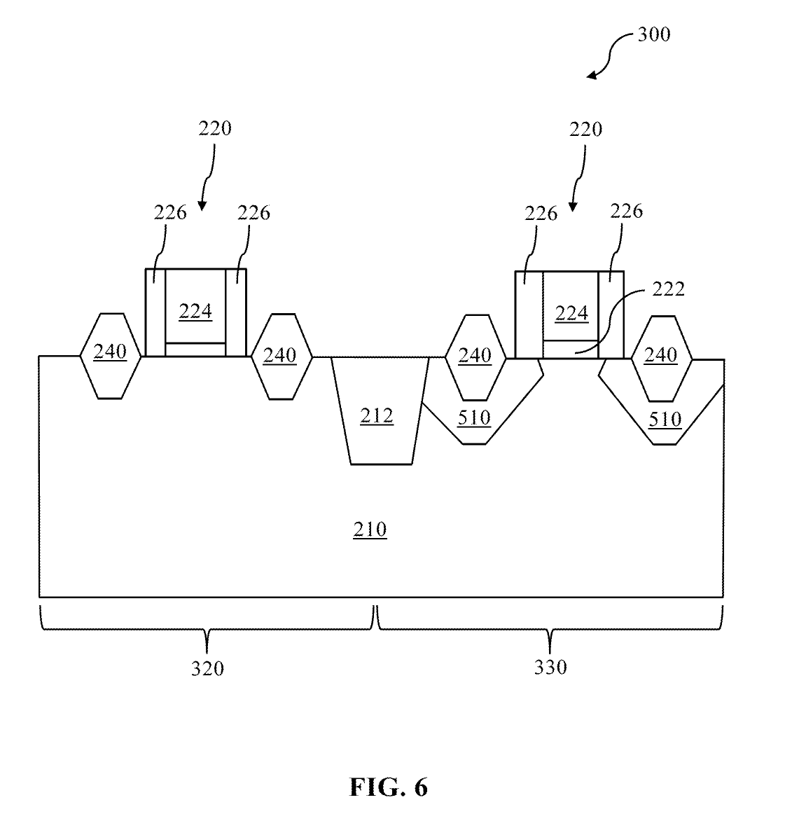

Referring FIGS. 1 and 6, the method 100 proceeds to step 108 by performing a second stage of the two-stage-striping process. In the present embodiment, the second stage is a wet etching process to remove the remaining photoresist layer 310. A chemical solution of the wet etching process may include hot sulfuric acid. Alternatively, chemical solutions may include various organic solvents, such as acetone, DHF methyl ethyl ketone and cellosolve.

A spin-and-dry process may be involved in the wet etching process. Spin and dry processes often present difficulties such as a protrusion structure breaking or peeling during the spinning process. In the present embodiments, however, such difficulties have been significantly reduced or eliminated.

In another embodiment, the patterned photoresist layer 310 covers the second region and exposes the first region. Then similar steps of 106-110 are implemented. In yet another embodiment, steps 104-108 can be repeated multiple times.

Additional steps can be provided before, during, and after the method 100, and some of the steps described can be replaced, eliminated, or moved around for additional embodiments of the method 100.

Based on the above, the present disclosure offers methods for removing photoresist layer after an ion-implantation. The method employs a two-stage-striping process that performing a low temperature dry strip first to substantially remove a hardened portion of a photoresist layer formed in the ion-implantation, then followed by a wet etch to remove remaining photoresist layer. The method has demonstrated reduction of protrusion structure breaking/peeling.

The present disclosure provides many different embodiments of fabricating a semiconductor device that provide one or more improvements over the prior art. In one embodiment, a method for fabricating a semiconductor device includes providing a substrate. The substrate has protrusion structures. The method also includes forming a patterned photoresist layer over the substrate, including covering the protrusion structures. The method also includes applying an ion-implantation to the substrate, including the patterned photoresist layer. Therefore an outer portion of the patterned photoresist layer formed a hardened portion. The method also includes performing a two-stage-striping process to remove the patterned photoresist layer. The two-stage-striping process is to perform a low-temperature-dry-etch first to substantially remove the hardened portion of the patterned photoresist layer, thereby leaving a remaining portion of the patterned photoresist layer. Then it is followed by a wet etch to remove the remaining patterned photoresist layer.

In another embodiment, a method for fabricating a semiconductor device includes providing a substrate providing a substrate. The substrate includes a first region and a second region. The substrate also includes a gate structure disposed in the first region. The method also includes coating a photoresist layer over the substrate, patterning the photoresist layer to cover the first region and expose the second region, applying an ion-implantation to the substrate, including the first region. A hardened portion is formed on an outer portion of the photoresist layer during the ion-implant. The method also includes after the ion-implantation, performing an etching process to remove the patterned photoresist layer. The etching process is configured to perform a low-temperature dry etching first to substantially remove the hardened portion of the photoresist layer. Then it followed by a wet etching process to remove remaining photoresist layer.

In yet another embodiment, a method for fabricating a semiconductor device includes providing a substrate having polysilicon gate stacks, forming a patterned photoresist layer over the substrate. The patterned photoresist layer covers a first region and un-cover a second region of the substrate. The polysilicon gate stack is covered by the patterned photoresist in the first region while another polysilicon gate stack is un-covered by the patterned photoresist in the second region. The method also includes applying an ion-implant to the substrate. An outer portion of the patterned photoresist layer formed a hardened portion during the ion-implant. The method also includes performing a two-stage-striping process to remove the patterned photoresist layer. The two-stage-striping process includes performing a low-temperature-dry-etch first to substantially remove the hardened portion of the patterned photoresist layer, thereby leaving a remaining portion of the patterned photoresist layer. Then it is followed by performing a wet etch to remove the remaining patterned photoresist layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
providing a substrate having a protrusion structure;
forming a patterned photoresist layer over the substrate, including covering the protrusion structure;
applying an ion-implantation to the substrate, including to the patterned photoresist layer, wherein an outer portion of the patterned photoresist layer forms a hardened portion; and
performing a two-stage-striping process to remove the patterned photoresist layer, including:
performing a low-temperature-dry-etch to substantially remove the hardened portion of the patterned photoresist layer, thereby leaving a remaining portion of the patterned photoresist layer; and
performing a wet etch to remove the remaining patterned photoresist layer.

2. The method of claim 1, wherein the low-temperature-dry-etch utilizes a temperature less than 400° C.

3. The method of claim 1, wherein the low-temperature-dry-etch includes an oxygen-contained plasma ashing.

4. The method of claim 1, wherein a chemical solution of the wet etch includes hot sulfuric acid.

5. The method of claim 1, wherein the protrusion structure includes a first gate stack.

6. The method of claim 5, the substrate further comprising:
a first region covered by the patterned photoresist layer;
a second region not being covered by the patterned photoresist layer;
a second gate stack disposed over the second region;
a sidewall spacer disposed along sidewalls of both gate stacks; and
source/drain features disposed over the substrate and separated by the gate stacks.

7. The method of claim 6, wherein a doped region is formed under the source/drain features in the second region by the ion-implantation.

8. The method of claim 6, wherein the gate stacks include a polysilicon gate stack.

9. A method comprising:
providing a substrate, the substrate including a first region, a second region, and a gate structure disposed in the first region;
coating a photoresist layer over the substrate;
patterning the photoresist layer to cover the first region and expose the second region;
implanting the covered first region, wherein a hardened portion is formed on an outer portion of the photoresist layer; and
after implanting, performing an etching process, including:
a low-temperature dry etch to substantially remove the hardened portion of the photoresist layer; and
after the low-temperature dry etch, a wet etch process to remove the remaining photoresist layer.

10. The method of claim 9, wherein the low-temperature-dry-etch utilizes a temperature less than 400° C.

11. The method of claim 9, wherein the low-temperature-dry-etch includes an oxygen-contained plasma ashing.

12. The method of claim 9, wherein a chemical solution of the wet etch includes hot sulfuric acid.

13. The method of claim 9, the substrate further comprising:
another gate structure disposed over the second region;
a sidewall spacer disposed along sidewalls of the gate structure; and
source/drain features formed over the substrate, separated by the gate structures.

14. The method of claim 13, wherein a doped region is formed under the source/drain features in the second region by the ion-implantation.

15. The method of claim 13, wherein the gate structure includes a polysilicon gate stack.

16. A method comprising:
providing a substrate having first and second polysilicon gate stacks;
forming a patterned photoresist layer over the substrate, wherein the patterned photoresist layer covers a first region and leaves un-covered a second region of the substrate, wherein the first polysilicon gate stack is covered by the patterned photoresist in the first region while the second polysilicon gate stack is in the second region;
applying an ion-implant to the substrate, wherein an outer portion of the patterned photoresist layer forms a hardened portion; and
performing a two-stage-stripping process to remove the patterned photoresist layer, the two-stage-striping process including:
performing a low-temperature-dry-etch to substantially remove the hardened portion of the patterned photoresist layer, thereby leaving a remaining portion of the patterned photoresist layer; and
after the low-temperature dry-etch, performing a wet etch to remove the remaining patterned photoresist layer.

17. The method of claim 16, wherein the low-temperature-dry-etch utilizes a temperature less than 400° C.

18. The method of claim 16, wherein the low-temperature-dry-etch includes an oxygen-contained plasma ashing.

19. The method of claim 16, wherein a chemical solution of the wet etch includes hot sulfuric acid.

20. The method of claim 5, the substrate further comprising:
a sidewall spacer disposed along sidewalls of the polysilicon gate stack; and
source/drain features formed over the substrate, separated by the polysilicon gate stack.
